(19) United States
(12) Patent Application Publication
(10) Pub. No.: US 2026/0209564 A1
(43) Pub. Date: Jul. 23, 2026

(54) Multilayer structure with adhesive properties

(71) Applicant: Arkema France, Puteaux (FR)

(72) Inventors: Florent ABGRALL, Serquigny (FR); Dominique JOUSSET, Colombes Cedex (FR); Stéphane BIZET, Serquigny (FR); Mathieu SABARD, Serquigny (FR); David MESLET, Serquigny (FR)

(73) Assignee: Arkema France, Puteaux (FR)

(21) Appl. No.: 19/139,854

(22) PCT Filed: Dec. 15, 2023
(86) PCT No.: PCT/FR2023/052025

§ 371 Date: Jun. 16, 2025

(30) Foreign Application Priority Data
Dec. 16, 2022 (FR) 2213670

(51) Int. Cl. C09J 7/35; C09J 5/06; C09J 7/25; H10F 19/80

(52) U.S. Cl. CPC C09J 7/35; C09J 5/06; C09J 7/25; H10F 19/804; C09J 2203/322; C09J 2301/122; C09J 2301/124; C09J 2301/304; C09J 2301/414; C09J 2451/006

(57) ABSTRACT

Embodiments relate to a multilayer structure including an adhesive layer and, in direct contact therewith, a layer forming a support film, in which the adhesive layer includes a polyolefin A and a functionalized polyolefin and has a melting temperature of between 80° C. and 120° C., and in which the support film includes a polyamide graft polymer and has a flow temperature of greater than 160° C. Embodiments also relate to a process for manufacturing same, to the use of such a multilayer structure for manufacturing photovoltaic modules and to a process for manufacturing such modules, and also to these photovoltaic modules per se.

### FIELD OF THE INVENTION

The invention relates to a multilayer structure, notably a two-layer structure, which is notably useful as an encapsulant for photovoltaic modules. The invention also relates to photovoltaic modules comprising such a multilayer structure.

### TECHNICAL BACKGROUND

Global warming, related to the greenhouse gases given off by fossil fuels, has further galvanized interest in alternative energy solutions which do not emit such gases during the operation thereof, for instance photovoltaic modules.

Many types of photovoltaic module structure exist.

FIG. 1 shows a conventional photovoltaic cell; a photovoltaic cell (10) comprises individual cells (12), an individual cell containing a photovoltaic sensor (14) in contact with electron collectors (16) positioned above (upper collectors) and below (lower collectors) the photovoltaic sensor. The upper collectors (16) of an individual cell are connected to the lower collectors (16) of another individual cell (12) via conducting bars (18), also known as electrical interconnectors, generally made of a metal alloy. In other embodiments, the interconnectors are all located on the same side of the individual cells. All these individual cells (12) are connected together, in series and/or in parallel, to form the photovoltaic cell (10). When the photovoltaic cell (10) is placed under a light source, it delivers a direct electric current which can be recovered at the terminals (19) of the cell (10).

FIG. 2 represents a photovoltaic module (20) comprising the photovoltaic cell (10) of FIG. 1 encased in an encapsulant (22) composed of an upper part and of a lower part. The encapsulated cell is also protected by an upper protective layer (24) (also known as the frontsheet) and a protective layer on the back of the module (also known as the backsheet) (26). The upper protective layer (24), generally made of glass, provides the photovoltaic cell with shock and moisture protection. The protective layer on the back of the module (26), generally made of thermoplastic or crosslinkable resin, also contributes to its protection against moisture and, in addition, to the electrical insulation of the individual cells by avoiding any contact with the external environment.

In order to ensure effective protection, it is important that the encapsulant fills the space between the photovoltaic cell and the protective layers perfectly. In addition, its adhesion to the protective layers must be perfect and durable, even at temperatures of 80° C. or more which can be reached under solar radiation.

To promote adhesion, it is possible to use either “chemical” techniques by providing a specific binder or adhesion promoter, or physical techniques such as a surface treatment by corona or plasma effect. These methods, however, require additional operations that are sometimes complex for an often disappointing result and give rise to a non-negligible cost. Furthermore, physical surface treatments are not stable over time and require that storage and handling precautions be taken.

At present, to manufacture a photovoltaic module, the “frontsheet”, the encapsulant, the cell and the “backsheet” are assembled simultaneously, most often by a vacuum lamination process. The encapsulant is melted during the lamination step in order to coat the active layers of the cell. In addition to the handling of many films, this assembly process by lamination has drawbacks related to the shrinkage of the encapsulant film which can be up to 10%, sometimes even 50%. This shrinkage can lead to defects in the photovoltaic module such as air bubbles, pleats, blisters, defects in overlap on the edges or breaks in the connectors between individual cells. All these defects cause waste or can reduce the lifespan and efficiency of photovoltaic modules.

To limit these problems, the encapsulant film can be produced by an extrusion process followed by a post-annealing step, but this reduces the extrusion speed and therefore increases its cost.

Patent application EP 2 673 809 A1 discloses a two-layer film composed of a backsheet and an encapsulant making it possible to overcome at least some of these problems. However, the implementation of these two-layer structures requires successively stacking a first layer of encapsulant, the photovoltaic module, a second layer of encapsulant and finally a layer forming the backsheet, as shown in FIG. 2. In addition to a first layer of encapsulant 400 μm thick, two-layer structures 800 μm thick are thus described. The large thickness of these structures adds significant weight and cost. Moreover, the encapsulant does not offer sufficient adhesion with the metal to be used in processes comprising a prior lamination step on the surface of the metal interconnectors.

In addition, these two-layer films cannot be used for the preparation of photovoltaic modules having certain geometrical configurations, notably connections located on the same side as photovoltaic sensors, such as those described for example in patent application WO 2004/021 455, and that require laminating the encapsulant directly to the surface of the interconnectors.

There is thus a need for multilayer structures, notably for photovoltaic modules, which can overcome the drawbacks of the prior art, notably to improve the productivity of the preparation processes and the quality of photovoltaic modules, and which are versatile and therefore compatible with different geometrical configurations and processes for assembling photovoltaic modules.

### SUMMARY OF THE INVENTION

The aim of the present invention is to remedy the problems encountered in the prior art by proposing a multilayer structure, notably a two-layer structure, comprising an adhesive layer and a support film.

In its broadest definition, the invention is directed toward a multilayer structure comprising an adhesive layer that can serve as an encapsulant and a support film that can serve as a backsheet, characterized in that the adhesive layer comprises a polyolefin A and a functional polyolefin and has a specific melting point in that the support film has a specific flow temperature.

Specifically, it was found that by combining a polyolefin A with a functional polyolefin in the adhesive layer, it was possible to obtain a multilayer structure with both very good thermal stability and excellent adhesion to the metal of the electrical interconnectors of photovoltaic cells.

The better adhesion of the multilayer structure to the interconnectors has a twofold advantage. Firstly, it facilitates the assembly process, notably by avoiding prior surface treatments. Secondly, it ensures a reliable electrical contact between interconnectors and photovoltaic cells and thus gives photovoltaic modules better efficiency and a longer lifetime. Finally, the multilayer structures of the invention may be of small thickness, notably less than 100 μm.

The multilayer structures according to the invention thus allow the manufacture of photovoltaic modules that are both of better quality and less expensive.

Thus, the present invention relates to a multilayer structure comprising an adhesive layer and a layer forming a support film in direct contact therewith, in which
(a) said adhesive layer comprises:
   a polyolefin A chosen from a homopolymer of ethylene and a copolymer of ethylene and an α-olefin, a copolymer of ethylene and a vinyl ester of carboxylic acid, notably a vinyl acetate (EVA) or a (co)polymer including methyl, ethyl, propyl, n-butyl, sec-butyl, isobutyl or tert-butyl (meth)acrylate units; and
   a functionalized polyolefin, distinct from polyolefin A, comprising a polyolefin backbone containing a residue of at least one unsaturated monomer (Y), the unsaturated monomer residue (Y) being fixed to the backbone by grafting or copolymerization;
the melting temperature of the adhesive layer being between 80° C. and 120° C.,
b) said support film comprises a polyamide graft polymer comprising:
   a polyolefin backbone, representing from 50% to 95% by mass of the polyamide graft polymer, containing a residue of at least one unsaturated monomer (X) and at least one polyamide graft, representing from 5% to 50% by mass of said polyamide graft polymer, in which:
      the polyamide graft is attached to the polyolefin backbone by the unsaturated monomer residue (X) comprising a function that is capable of reacting by condensation reaction with a polyamide having at least one amine end and/or at least one carboxylic acid end,
      the unsaturated monomer residue (X) is fixed to the backbone by grafting or copolymerization,
      the polyolefin backbone and the polyamide graft being chosen such that said polyamide graft polymer has a flow temperature greater than 160° C., as measured by DSC according to ISO 11357-1:2016, ISO 11357-2:2020, ISO 11357-3:2018, said flow temperature being defined as the highest temperature among the melting temperatures and the glass transition temperatures of the polyamide graft and of the polyolefin backbone.

Other advantageous features of the invention are the following:
the melting temperature of said adhesive layer is between 90° C. and 110° C.,
said adhesive layer has a Melt Flow Index (MFI), as measured according to the ASTP standard D 1238 at 190° C. under 2.16 kg, of between 0.2 and 10 g/10 min, preferably between 0.4 and 3 g/10 min, and in particular between 0.6 and 2 g/10 min,
said adhesive layer comprises:
   from 65% to 95% by weight of polyolefin A;
   from 5% to 35% by weight of functional polyolefin; and
   from 0 to 5% by weight of one or more additives.
the thickness of said adhesive layer is between 20 and 60 μm.
the thickness of said support film is between 5 and 40 μm.
the α-olefin comonomer of polyolefin A of the adhesive layer is chosen from ethylene-propylene, ethylene-butene and ethylene-octene.
the functional polyolefin of the adhesive layer is a polyolefin containing a residue of at least one unsaturated monomer (Y) which is a maleic anhydride.
said support film has a Melt Flow Index (MFI), as measured according to the ASTP standard D 1238 at 230° C. under 2.16 kg of between 0.2 and 10 g/10 min, preferably between 0.4 and 3 g/10 min, in particular between 0.6 and 2 g/10 min.
said support film bears said adhesive layer on one of its faces.
said support film bears said adhesive layer on both faces.
said support film is assembled to said adhesive layer by coextrusion.

According to another aspect, the invention is directed toward the use of such a multilayer structure for manufacturing photovoltaic modules. According to yet another aspect, the invention is directed toward a process for preparing a photovoltaic module, in which a photovoltaic cell is encapsulated with such a multilayer structure.

In this process, encapsulation can include the steps of:
(i) attaching an electrically conductive filament to the surface of said adhesive layer of such a multilayer structure at a temperature below the melting temperature of said adhesive layer to form an assembly;
(ii) placing said assembly in contact with a photovoltaic cell at a temperature between the melting temperature of the adhesive layer and the flow temperature of the support film.

Finally, according to a last aspect, the invention is directed toward a photovoltaic module comprising such a multilayer structure.

### DESCRIPTION OF THE FIGURES

The description which follows is given solely by way of illustration and without implied limitation with reference to the appended figures, in which:

FIG. 1 represents an example of a photovoltaic cell, parts (a) and (b) being ¾ views, part (a) showing an individual cell before connection and part (b) a view after connection of two individual cells; part (c) is a top view of a complete photovoltaic cell; and

FIG. 2 represents a cross section of a photovoltaic module, the “conventional” photovoltaic sensor of which is encapsulated by an upper encapsulant film and a lower encapsulant film.

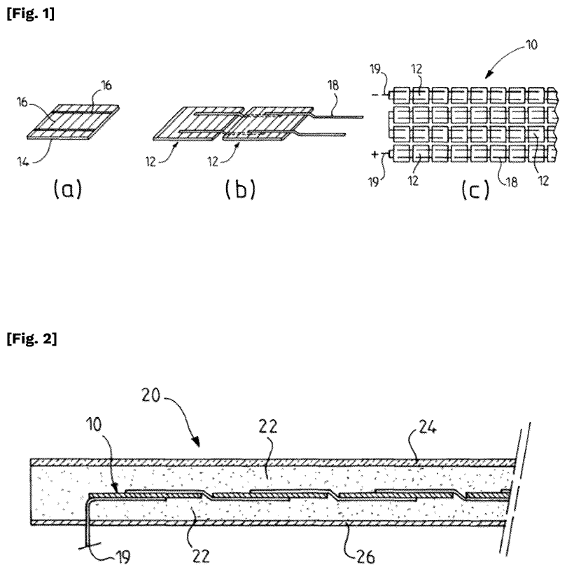

### DESCRIPTION OF THE INVENTION

Thus, according to a first aspect, the invention relates to a multilayer structure, notably as an encapsulant for a photovoltaic cell, comprising an adhesive layer and a layer forming a support film in direct contact therewith, in which the adhesive layer comprises a polyolefin A and a functionalized polyolefin, the melting temperature of the adhesive layer being between 80° C. and 120° C., and in which the support film comprises a specific polyamide graft polymer having a flow temperature of greater than 160° C., as measured by DSC according to ISO 11357-1:2016, ISO 11357-2:2020, ISO 11357-3:2018, the flow temperature being defined as the highest temperature among the melting temperatures and glass transition temperatures of the polyamide graft and the polyolefin backbone.

### A. Multilayer Structure

According to the invention, the adhesive layer of the multilayer structure is in direct contact with the support film.

In the absence of additional layers, the multilayer structure can form a two-layer structure. Nevertheless, it may also comprise other layers, in principle any layer. According to a preferred embodiment, the multilayer structure may be a three-layer structure, and may notably include a support film provided with an adhesive layer as defined below on both faces.

### A.1. Adhesive Layer

According to the invention, the adhesive layer of the multilayer structure includes a specific polyolefin A and a distinct functional polyolefin, the melting temperature of the adhesive layer being between 80° C. and 120° C. The polyolefins will be described in greater detail below.

### Polyolefin A

Polyolefin A present in the adhesive layer may be an ethylene homopolymer or a copolymer of ethylene with a comonomer chosen from an α-olefin, an alkyl (meth)acrylate or a vinyl ester of a carboxylic acid, notably a vinyl acetate. In the copolymer, the α-olefin may include 3 to 30 and notably 3 to 8 carbon atoms. Examples of α-olefins that may be mentioned include propylene, 1-butene, 1-pentene, 3-methyl-1-butene, 1-hexene, 4-methyl-1-pentene, 3-methyl-1-pentene, 1-octene, 1-decene, 1-dodecene, 1-tetradecene, 1-hexadecene, 1-octadecene, 1-eicosene, 1-docosene, 1-tetracosene, 1-hexacosene, 1-octacosene and 1-triacontene.

These α-olefins can be used alone or as a mixture of two or of more than two.

Preferably, the ethylene-α-olefin copolymers comprise an ethylene mass content of greater than 50%.

Ethylene-α-olefin copolymers are obtained via processes known to those skilled in the art, such as Ziegler-Natta, metallocene or organometallic polymerization described, for example, in WO 2008/036 707. Particularly preferred as polyolefin A is a polyethylene, notably of linear low density (LLDPE), or a copolymer of ethylene with a single α-olefin, chosen from ethylene-propylene, ethylene-butene and ethylene octene. According to another embodiment, polyolefin A is a copolymer of ethylene and alkyl (meth)acrylate, the term “alkyl (meth)acrylate” including alkyl acrylates or methacrylates. The alkyl chains of these (meth)acrylates may contain up to 30 carbon atoms. Alkyl chains that may be mentioned include methyl, ethyl, propyl, n-butyl, sec-butyl, isobutyl, tert-butyl, pentyl, hexyl, heptyl, octyl, 2-ethylhexyl, nonyl, decyl, undecyl, dodecyl, tridecyl, tetradecyl, pentadecyl, hexadecyl, heptadecyl, octadecyl, nonadecyl, eicosyl, hencosyl, docosyl, tricosyl, tetracosyl, pentacosyl, hexacosyl, heptacosyl, octacosyl and nonacosyl. Methyl, ethyl and butyl (meth)acrylates are preferred.

Ethylene-alkyl (meth)acrylate copolymers are conventionally obtained via processes known to those skilled in the art, for instance the autoclave or tubular high-pressure process.

According to a particularly preferred embodiment, polyolefin A is a copolymer of ethylene and vinyl acetate (EVA).

Preferably, the polyolefin A has a melting temperature of between 90° C. and 110° C., and in particular between 90° C. and 105° C.

According to one embodiment, the heat of fusion of polyolefin A is less than 130 J/g, and notably between 80 and 120 J/g (second heating of DSC according to ISO 11347 at 40° C./min).

The density of polyolefin A, measured according to the ASTM standard D 1505, is preferably from 0.860 to 0.960, in particular from 0.860 to 0.920. Specifically, without wishing to limit itself to a particular theory, the Applicant was able to observe that a low heat of fusion, within the range mentioned above, reflecting a low degree of crystallinity, made it possible to favourably influence the adhesion of the adhesive layer to the metal.

### Functional Polyolefin

For the purposes of the present description, the term “functional polyolefin” means a polyolefin distinct from polyolefin A present in the adhesive layer and comprising reactive functions, and capable of reacting in contact with a metal surface.

Such reactive functions are notably epoxide, carboxylic acid, carboxylic acid anhydride, carboxylic acid amide and carboxylic acid ester functions. The functionalized polyolefin present in the adhesive layer comprises a polyolefin backbone containing a residue of at least one unsaturated monomer (Y) chosen from an unsaturated epoxide, an unsaturated carboxylic acid anhydride, an unsaturated carboxylic acid, or a salt thereof, the unsaturated monomer residue (Y) being fixed to the backbone by grafting or copolymerization.

These functions promote interaction with the metal surface in contact with the electrical interconnectors, which improves the adhesion between the multilayer structure and the electrical interconnectors.

The functional polyolefins may notably be derived from monomers such as meth (acrylic acid), (meth)acrylamide or vinyl acetate.

According to one embodiment, the polyolefin backbone of the functional polyolefin is a polyethylene backbone, notably an ethylene homopolymer or copolymer.

The unsaturated monomer (Y) may be an unsaturated epoxide, notably chosen from aliphatic glycidyl esters and ethers such as allyl glycidyl ether, vinyl glycidyl ether, glycidyl maleate and itaconate, glycidyl acrylate and methacrylate; alicyclic glycidyl esters and ethers such as 2-cyclohexene-1-glycidyl ether, cyclohexene-4,5-diglycidyl carboxylate, cyclohexene-4-glycidyl carboxylate, 5-norbornene-2-methyl-2-glycidyl carboxylate and endocisbicyclo(2,2,1)-5-heptene-2,3-diglycidyl dicarboxylate, glycidyl methacrylate being preferred.

As a variant, the unsaturated monomer (Y) may be an unsaturated carboxylic acid or a salt thereof, notably acrylic acid or methacrylic acid and salts thereof.

As a variant, the unsaturated monomer (Y) may be an unsaturated carboxylic acid ester, notably an alkyl (meth)acrylate, the term “alkyl (meth)acrylate” including alkyl acrylates or methacrylates. The alkyl chains of these (meth)acrylates may contain up to 30 and notably up to 24 carbon atoms. Alkyl chains that may be mentioned include methyl, ethyl, propyl, n-butyl, sec-butyl, isobutyl, tert-butyl, pentyl, hexyl, heptyl, octyl, 2-ethylhexyl, nonyl, decyl, undecyl, dodecyl, tridecyl, tetradecyl, pentadecyl, hexadecyl, heptadecyl, octadecyl, nonadecyl, eicosyl, hencosyl, docosyl, tricosyl, tetracosyl, pentacosyl, hexacosyl, heptacosyl, octacosyl and nonacosyl, in particular methyl, ethyl, and butyl (meth)acrylates. As a variant, the unsaturated monomer (Y) may be a carboxylic acid anhydride, notably chosen from maleic, itaconic, citraconic, allylsuccinic, cyclohex-4-ene-1,2-dicarboxylic, 4-methylenecyclohex-4-ene-1,2-dicarboxylic, bicyclo(2,2,1) hept-5-ene-2,3-dicarboxylic and x-methylbicyclo(2,2,1) hept-5-ene-2,2-dicarboxylic anhydrides. Among these, maleic anhydride is preferred.

The unsaturated monomer (Y) may also be a vinyl ester of a carboxylic acid, notably a vinyl acetate.

As a variant, the unsaturated monomer (Y) may also be a (meth)acrylamide, chosen from acrylamide and methacrylamide. The unsaturated monomer (Y) in the functional polyolefin is fixed by grafting or copolymerization.

Preferably, the functional polyolefin does not comprise any polyamide grafts.

Preferably, the functional polyolefin is an ethylene copolymer containing an unsaturated carboxylic acid anhydride residue, notably maleic anhydride.

The ethylene copolymer may be a copolymer of ethylene and of a comonomer chosen from esters of unsaturated carboxylic acids, for instance alkyl acrylates or alkyl methacrylates grouped under the term “alkyl (meth)acrylates” as specified above.

Copolymers of ethylene and of esters of unsaturated carboxylic acids can be obtained via processes known to those skilled in the art, for instance the autoclave or tubular high pressure process.

In a preferred embodiment, the functional polyolefin is an ethylene-alkyl (meth)acrylate-maleic anhydride terpolymer.

According to one embodiment, the adhesive layer comprises at least 65% by weight of a polyolefin A as defined above.

According to another embodiment, the adhesive layer comprises at least 5% by weight of a functional polyolefin.

According to a preferred embodiment, the adhesive layer comprises:
from 65% to 95% by weight of a polyolefin A as defined above,
from 5% to 30% by weight of a functional polyolefin; and
from 0 to 5% by weight of additives, notably chosen from plasticizers, adhesion promoters, UV stabilizers, UV absorbers, antioxidants and pigments.

Plasticizers could be added to the adhesive layer in order to facilitate the implementation and to improve the productivity of the process for manufacturing the multilayer structures and/or photovoltaic modules. Examples that will be mentioned include paraffinic, aromatic or naphthalenic mineral oils that can also improve the adhesiveness of the structures according to the invention. Mention may also be made, as plasticizer, of phthalates, azelates, adipates or tricresyl phosphate. Colouring or brightening compounds may also be added.

Similarly, adhesion promoters, although not necessary, can advantageously be added in order to further improve the adhesiveness of the structure. The adhesion promoter is a non-polymeric ingredient; it may be organic, crystalline or inorganic and more preferentially semi-inorganic semi-organic. Among these, mention may be made of organic titanates or silanes, for instance monoalkyl titanates, trichlorosilanes and trialkoxysilanes. Advantageously, trialkoxysilanes containing an epoxy, vinyl or amine group will be used, in particular when these adhesion promoters are added in the form of a masterbatch. Provision may also be made for these adhesion promoters to be diluted or mixed with the functional or non-functional polyolefin of the adhesive layer via a technique well known to those skilled in the art, for example compounding.

Since UV radiation can cause slight yellowing of the adhesive layer, UV stabilizers and UV absorbers such as benzotriazole, benzophenone and other hindered amines may be added to the adhesive layer and/or to the support film to extend the transparency of the multilayer structure and thus its lifetime.

The adhesive layer may moreover comprise 0 to 5% by weight, notably 0.1% to 4.5%, in particular 0.5% to 4% and most particularly 1% to 3% by weight of one or more of these additives, relative to the total weight of the composition.

The adhesive layer may moreover comprise one or more antioxidants to limit yellowing during manufacture of the adhesive layer. Preferred antioxidants are, for example, phosphorus compounds (phosphonites and/or phosphites) and hindered phenolics.

The adhesive layer may notably comprise 0 to 3% by weight, notably 0.1% to 2.5%, in particular 0.5% to 2% and most particularly 1% to 1.5% by weight of one or more antioxidants relative to the total weight of the composition.

It is also possible to add pigments to the adhesive layer, for instance coloring compounds or brightening compounds in proportions generally ranging from 0.01% to 2%, relative to the total mass of the composition. According to one embodiment, the thickness of the adhesive layer is between 20 and 60 μm.

The melting temperature of the adhesive layer is preferably between 80° C. and 110° C., preferably between 90° C. and 100° C.

Specifically, the inventors have observed that if the melting temperature is lower, the multilayer structure may be difficult to handle, notably during the step of coextrusion with the support film and/or during its subsequent use, notably during the lamination step on the surface of the filaments. Conversely, a melting temperature above 120° C. is usually accompanied by a higher degree of crystallinity which can reduce the adhesion to metal filaments.

According to one embodiment, the adhesive layer has a Melt Flow Index (MFI) of between 0.2 and 10 g/10 min, preferably between 0.4 and 3 g/10 min, and more preferentially between 0.6 and 2 g/10 min, measured according to the ASTM standard D1238 at 190° C./2.16 kg.

### A.2. Support Film

The support film comprises a polyamide graft polymer comprising a polyolefin backbone containing a residue of at least one unsaturated monomer (X) and at least one polyamide graft, the polyamide graft being attached to the polyolefin backbone by the unsaturated monomer residue (X) comprising a function that is capable of reacting by a condensation reaction with a polyamide, the polyolefin backbone and the polyamide graft being chosen so that said polyamide graft polymer has a flow temperature of greater than 160° C.

The flow temperature of the polyamide graft polymer is defined as the highest temperature among the melting temperatures and the glass transition temperatures of the polyamide grafts and of the polyolefin backbone. The backbone and the grafts are chosen so that the flow temperature of the polyamide graft polymer is greater than 160° C. The polyamide graft polymer includes 50% to 95%, preferably 60% to 90% and in particular 70% to 85% by mass of a polyolefin backbone containing a residue of at least one unsaturated monomer (X).

As regards the polyolefin backbone, it is preferably a polymer comprising as monomer an α-olefin, notably including 2 to 30 carbon atoms.

Examples of α-olefins that may be mentioned include ethylene, propylene, 1-butene, 1-pentene, 3-methyl-1-butene, 1-hexene, 4-methyl-1-pentene, 3-methyl-1-pentene, 1-octene, 1-decene, 1-dodecene, 1-tetradecene, 1-hexadecene, 1-octadecene, 1-eicosene, 1-docosene, 1-tetracosene, 1-hexacosene, 1-octacosene and 1-triacontene.

Mention may also be made of cycloolefins containing 3 to 30 and notably 3 to 20 carbon atoms, such as cyclopentane, cycloheptene, norbornene, 5-methyl-2-norbornene, tetracyclododecene, and 2-methyl-1,4,5,8-dimethano-1,2,3,4,4a,5,8,8a-octahydronaphthalene; di- and polyolefins, such as butadiene, isoprene, 4-methyl-1,3-pentadiene, 1,4-pentadiene, 1,5-hexadiene, 1,3-hexadiene, 1,3-octadiene, 1,4-octadiene, 1,5-octadiene, 1,6-octadiene, ethylidenenorbornene, vinylnorbornene, dicyclopentadiene, 7-methyl-1,6-octadiene, 4-ethylidene-8-methyl-1,7-nonadiene, and 5,9-dimethyl-1,4,8-decatriene; vinyl aromatic compounds such as mono- or poly-alkylstyrenes (including styrene, o-methylstyrene, m-methylstyrene, p-methylstyrene, o,p-dimethylstyrene, o-ethylstyrene, m-ethylstyrene and p-ethylstyrene), and derivatives comprising functional groups such as methoxystyrene, ethoxystyrene, vinylbenzoic acid, methylvinyl benzoate, benzylvinyl acetate, hydroxystyrene, o-chlorostyrene, p-chlorostyrene, divinylbenzene, 3-phenylpropene, 4-phenylpropene, α-methylstyrene, vinyl chloride, 1,2-difluoroethylene, 1,2-dichloroethylene, tetrafluoroethylene and 3,3,3-trifluoro-1-propene, propylene and ethylene being preferred. The polyolefin may be a homopolymer when only one α-olefin is polymerized. Examples that may be mentioned are polyethylene (PE) or polypropylene (PP). It may also be a copolymer when at least two comonomers are copolymerized in the polymer chain, the first of the at least two monomers being an α-olefin and the other comonomers a monomer capable of polymerizing with the first monomer.

Other comonomers that may be mentioned include:
one of the α-olefins already mentioned above, different from the first α-olefin comonomer;
dienes, for instance 1,4-hexadiene, ethylidene, norbornene or butadiene;
esters of unsaturated carboxylic acids such as alkyl acrylates or alkyl methacrylates grouped under the term “alkyl (meth)acrylates”. The alkyl chains of these (meth)acrylates may contain up to 30 carbon atoms. Alkyl chains that may be mentioned include methyl, ethyl, propyl, n-butyl, sec-butyl, isobutyl, tert-butyl, pentyl, hexyl, heptyl, octyl, 2-ethylhexyl, nonyl, decyl, undecyl, dodecyl, tridecyl, tetradecyl, pentadecyl, hexadecyl, heptadecyl, octadecyl, nonadecyl, eicosyl, hencosyl, docosyl, tricosyl, tetracosyl, pentacosyl, hexacosyl, heptacosyl, octacosyl and nonacosyl, methyl, ethyl and butyl (meth)acrylates being preferred; and
vinyl esters of carboxylic acids. As examples of vinyl esters of carboxylic acids, mention may be made of vinyl acetate, vinyl versatate, vinyl propionate, vinyl butyrate or vinyl maleate, vinyl acetate being preferred.

Advantageously, the polyolefin backbone consists of at least 50 mol % of the first comonomer.

The preferred polyolefin backbones consist of ethylene/alkyl (meth)acrylate copolymer. By using this polyolefin backbone, an excellent resistance to light-mediated and temperature-mediated aging is obtained. According to the present invention, the polyolefin backbone contains at least one unsaturated monomer residue (X) that is capable of reacting with an acid and/or amine function of the polyamide graft via a condensation reaction. It is pointed out that this unsaturated monomer (X) is not a “second comonomer”.

As unsaturated monomer (X), mention may be made of:
unsaturated epoxides. These include aliphatic glycidyl esters and ethers such as allyl glycidyl ether, vinyl glycidyl ether, glycidyl maleate and itaconate, glycidyl acrylate and methacrylate; alicyclic glycidyl esters and ethers such as 2-cyclohexene-1-glycidyl ether, cyclohexene-4,5-diglycidyl carboxylate, cyclohexene-4-glycidyl carboxylate, 5-norbornene-2-methyl-2-glycidyl carboxylate and endocisbicyclo(2,2,1)-5-heptene-2,3-diglycidyl dicarboxylate, glycidyl methacrylate being preferred.
unsaturated carboxylic acids and salts thereof, for example acrylic acid or methacrylic acid and salts thereof.
carboxylic acid anhydrides chosen, for example, from maleic, itaconic, citraconic, allylsuccinic, cyclohex-4-ene-1,2-dicarboxylic, 4-methylenecyclohex-4-ene-1,2-dicarboxylic, bicyclo(2,2,1) hept-5-ene-2.3-dicarboxylic and x-methylbicyclo(2,2,1) hept-5-ene-2,2-dicarboxylic anhydrides, in particular maleic anhydride.

The unsaturated monomer (X) is preferably chosen from an unsaturated carboxylic acid anhydride and an unsaturated epoxide. In particular, to perform the condensation of the polyamide graft with the polyolefin backbone, in the case where the reactive end of the polyamide graft is a carboxylic acid function, the unsaturated monomer (X) is preferentially an unsaturated epoxide. In the case where the reactive end of the polyamide graft is an amine function, the unsaturated monomer (X) is advantageously an unsaturated epoxide and preferentially an unsaturated carboxylic acid anhydride.

According to an advantageous version of the invention, the preferred number of unsaturated monomers (X) fixed on average to the polyolefin backbone is greater than or equal to 1.3 and/or preferentially less than or equal to 10.

Thus, if (X) is maleic anhydride and the number-average molar mass of the polyolefin is 15 000 g/mol, it has been found that this corresponds to an anhydride proportion of at least 0.8% by mass of the entire polyolefin backbone and of at most 6.5%. These values associated with the mass of the polyamide grafts determine the proportion of polyamide and of backbone in the polyamide graft polymer.

The polyolefin backbone containing the unsaturated monomer residue (X) is obtained by polymerization of the monomers (first comonomer, optional second comonomer, and optionally unsaturated monomer (X)). This polymerization can be performed via a high-pressure radical process or a solution process, in an autoclave or tubular reactor, these processes and reactors being well known to those skilled in the art. When the unsaturated monomer (X) is not copolymerized in the polyolefin backbone, it is grafted onto the polyolefin backbone. Grafting is also an operation that is known per se. The composition would be in accordance with the invention if several different functional monomers (X) were copolymerized and/or grafted onto the polyolefin backbone.

Depending on the types and ratio of monomers, the polyolefin backbone may be semicrystalline or amorphous. For amorphous polyolefins, only the glass transition temperature is observed, whereas for semicrystalline polyolefins, a glass transition temperature and a melting temperature are observed. It is possible to obtain a polyolefin backbone with the desired glass transition and melting temperature, if any, by adjusting the type and the ratio of the monomers. The molar mass of the polyolefin backbone can be modified to obtain the desired viscosity.

The polyolefin backbone has a Melt Flow Index (MFI) preferably between 3 and 400 g/10 min, in particular between 10 and 300 g/10 min and notably between 50 and 200 g/10 min (190° C., 2.16 kg, ASTM D 1238).

Preferably, its density, as measured according to the standard ISO 1183:2019, is advantageously between 0.91 and 0.96.

The polyamide graft polymer comprises a polyolefin backbone containing a residue of at least one unsaturated monomer (X) as described above and at least one polyamide graft attached to the polyolefin backbone via the unsaturated monomer residue (X).

The polyamide grafts can be homopolyamides or copolyamides. The polyamide grafts may notably be aliphatic, cycloaliphatic or semiaromatic. Among the homopolyamides that are preferred are aliphatic polyamides which result from the polycondensation:
of a lactam,
of an aliphatic α,ω-aminocarboxylic acid, or
of an aliphatic diamine and an aliphatic diacid.

As examples of lactams, mention may be made of caprolactam, oenantholactam and lauryllactam.

As examples of aliphatic α,ω-aminocarboxylic acids, mention may be made of aminocaproic acid, 7-aminoheptanoic acid, 11-aminoundecanoic acid and 12-aminododecanoic acid.

As examples of aliphatic diamines, mention may be made of hexamethylenediamine, dodecamethylenediamine and trimethylhexamethylenediamine.

As examples of aliphatic diacids, mention may be made of adipic acid, azelaic acid, suberic acid, sebacic acid and dodecanedicarboxylic acid. Among the aliphatic homopolyamides, examples that may be mentioned, in a nonlimiting manner, include the following polyamides: polycaprolactam (PA6); polyundecanamide (PA 11); polylauryllactam (PA12); polybutylene adipamide (PA4.6); polyhexamethyleneadipamide (PA6.6); polyhexamethylene azelamide (PA6.9); polyhexamethylene sebacamide (PA-6.10); polyhexamethylene dodecanamide (PA6.12); polydecamethylene dodecanamide (PA 10.12); polydecamethylene sebacanamide (PA 10.10) and polydodecamethylene dodecanamide (PA 12.12). PA6 is particularly preferred.

Among the cycloaliphatic homopolyamides, mention may notably be made of those resulting from the condensation of a cycloaliphatic diamine and of an aliphatic diacid.

Examples of cycloaliphatic diamine that may be mentioned include 4,4′-methylenebis(cyclohexylamine), also called para-bis(aminocyclohexyl) methane or PACM, and 2,2′-dimethyl-4,4′-methylenebis(cyclohexylamine), also called bis(3-methyl-4-aminocyclohexyl) methane or BMACM.

Among the cycloaliphatic homopolyamides, mention may be made notably of the polyamides PACM.12, BMACM.10 and BMACM.12.

The semiaromatic homopolyamides may result from condensation:
of an aliphatic diamine and an aromatic diacid, such as terephthalic acid (T) and isophthalic acid (I). The polyamides obtained are then commonly called “polyphthalamides” or PPA;
of an aromatic diamine, such as xylylenediamine, and more particularly meta-xylylenediamine (MXD) and an aliphatic diacid.

In this polyamide family, mention may be made notably of the polyamides 6.T, 6.I, MXD.6 and MXD.10.

As a variant, the polyamide grafts are copolyamides. The latter result from the polycondensation of at least two of the monomers mentioned above to obtain homopolyamides.

The term “monomer” in the present description of the copolyamides should be taken as meaning “repeating unit”. Specifically, the case where a repeating unit of the PA consists of the combination of a diacid with a diamine is particular. It is considered that it is the combination of a diamine and a diacid, that is to say the diamine.diacid pair (in an equimolar amount), which corresponds to the monomer. This is explained by the fact that, individually, the diacid or the diamine is only a structural unit, which is not enough by itself alone to polymerize to give a polyamide.

Thus, copolyamides notably cover condensation products:
of at least two lactams,
of at least two aliphatic α,ω-aminocarboxylic acids,
of at least one lactam and at least one aliphatic α,ω-aminocarboxylic acid,
of at least two diamines and at least two diacids,
of at least one lactam with at least one diamine and at least one diacid,
of at least one aliphatic α,ω-aminocarboxylic acid with at least one diamine and at least one diacid,
   the diamine(s) and the diacid(s) possibly being, independently of each other, aliphatic, cycloaliphatic or aromatic.

Depending on the types and ratio of monomers, the copolyamides may be semicrystalline or amorphous. Among the amorphous copolyamides, mention may be made, for example, of copolyamides containing semiaromatic monomers.

It is also possible to use semicrystalline copolyamides and particularly copolyamides PA 6/11, PA 6/12 and PA Jun. 11, 2012.

The number-average molecular mass Mn of the copolyamides, as measured according to the standard ISO 16014-5:2019, may vary within wide proportions, but it is advantageously less than 10 000 g/mol. Advantageously, the polyamide grafts are monofunctional.

In order for the polyamide graft to have a monoamine end group, use may be made of a chain limiter of the formula:

R₁R₂NH
in which:
   R1 is hydrogen or a linear or branched alkyl group containing up to 20 carbon atoms,
   R2 is a group containing up to 20 linear or branched alkyl or alkenyl carbon atoms, a saturated or unsaturated cycloaliphatic radical, an aromatic radical or a combination thereof. The chain limiter may be, for example, laurylamine or oleylamine.

In order for the polyamide graft to have a monocarboxylic acid end group, use may be made of a chain limiter of formula R′1-COOH), R′1-CO—O—CO—R′2 or a dicarboxylic acid.

R′1 and R′2 are linear or branched alkyl groups containing up to 20 carbon atoms.

Advantageously, the polyamide graft has an end bearing an amine functionality. The preferred monofunctional polymerization chain limiters are laurylamine and oleylamine.

Advantageously, the molar mass of the polyamide grafts is between 1000 and 5000 g/mol and preferably between 2000 and 3000 g/mol.

The polycondensation defined above is performed according to known processes, for example at a temperature of between 20° and 300° C., under vacuum or under an inert atmosphere, with stirring of the reaction mixture. The average chain length of the graft is determined by the initial mole ratio between the polycondensable monomer or lactam and the chain limiter. For the calculation of the average chain length, one chain limiter molecule is usually counted per one graft chain.

A polyamide graft may be prepared with the desired glass transition and melting temperature, if any, by selecting the appropriate types and ratio of monomers. The viscosity of the polyamide graft may be adjusted by modulating the molar mass of the polyamide graft.

The condensation reaction of the polyamide graft on the polyolefin backbone containing the residue (X) is performed by reaction of an amine or acid function of the polyamide graft on the residue (X). Advantageously, monoamine polyamide grafts are used and amide or imide bonds are created by reacting the amine function with the function of the residue (X). This condensation is preferably performed in the molten state. Conventional mixing and/or extrusion techniques may be used to manufacture the composition. The components of the composition are thus mixed to form a compound which can optionally be granulated at the die outlet. Advantageously, coupling agents are added during compounding. To obtain a nanostructured composition, the polyamide graft and the backbone can thus be mixed in an extruder, at a temperature generally between 20° and 300° C. The mean residence time of the melt in the extruder may be between 5 seconds and 5 minutes, and preferably between 20 seconds and 1 minute. The yield of this condensation reaction is evaluated by selective extraction of the free polyamide grafts, i.e. those which have not reacted to form the polyamide graft polymer.

The preparation of polyamide grafts with an amine end and their addition to a polyolefin backbone containing the residue (X) is described in patents U.S. Pat. Nos. 3,976,720, 3,963,799, 5,342,886 and FR 2 291 225. The polyamide graft polymer of the present invention advantageously has a nanostructured organization. To obtain this type of organization, grafts having a number-average molar mass Mn of between 1000 and 5000 g/mol and more preferentially between 2000 and 3000 g/mol will preferentially be used, for example.

The particularly preferred polyamide graft polymer contains the residue of a carboxylic acid anhydride monomer, in particular a maleic anhydride monomer and polyamide 6 (PA6) grafts.

The graft polymer includes 5% to 50% by mass and preferably 15% to 30% by mass of polyamide grafts.

According to one embodiment, the polyamide graft polymer has a melting temperature of greater than 120° C.

Advantageously, the melting temperature of the support film is also higher than that of the adhesive layer, which makes it possible to provide thermomechanical stability to the structure. Preferably, the difference between the melting temperature of the support film and the melting temperature of the adhesive layer is between 3° and 60° C. According to one embodiment, the support film has a Melt Flow Index (MFI) of between 0.2 and 10 g/10 min, preferably between 0.4 and 3 g/10 min, and more preferentially between 0.6 and 2 g/10 min (230° C., 2.16 kg, ASTM D 1238).

According to another embodiment, the thickness of the support film is between 15 and 60 μm and is notably of the order of 20 μm. As mentioned above, the support film may be in direct contact with a second adhesive layer so as to form an adhesive layer/support film/adhesive layer three-layer structure, the second adhesive layer being as defined previously, identical to or different from the first.

### B. Process for Preparing the Multilayer Structure

The multilayer structure according to the invention may be obtained from mixtures intended for the adhesive layer and the support film via conventional techniques for producing films, sheets or plates. By way of example, mention may be made of the techniques of extrusion blow-molding of a sheath (also called a “blown film”), extrusion lamination, extrusion coating, extrusion of a flat film (also called a “cast film”) or even extrusion of sheets. All these techniques are known to the person skilled in the art and he will be able to adapt the conditions of implementation of the various techniques (temperature of the extruders, coupling, dies and feedblock, speed of rotation of the screws, cooling temperatures of the cooling cylinders, etc.) to form the structure according to the invention having the desired shape and thicknesses. It would not be departing from the invention if the final structure were obtained by pressing techniques, laminating with adhesives via a solvent-based or aqueous route, or if the final structure underwent an additional annealing step.

The multilayer structure is preferably prepared by coextrusion, in particular by flat film coextrusion.

During the coextrusion of the two layers, the layer of the support film is generally heated to a temperature higher than that of the adhesive layer, so that their viscosity, at their respective temperature, is as close as possible.

### C. Use for Manufacturing a Photovoltaic Module

According to a second aspect, the invention relates to the use of a multilayer structure as defined previously for the manufacture of a photovoltaic module.

The multilayer structure according to the invention is interesting in this application because it greatly facilitates the assembly of the photovoltaic cell with the encapsulant and the upper protective layers (called the front-sheet) and on the back of the module (called the back-sheet). In particular, this structure is suited to the manufacture of modules as described in patent application WO 2004/021 455 which requires that the encapsulant be laminated directly to the surface of the interconnectors. Specifically, good adhesion to the metal of the adhesive layer of the multilayer structure of the invention makes it possible to laminate the interconnectors beforehand on the multilayer structure, which makes assembly of the photovoltaic module much simpler.

It may be advantageous to use the multilayer structure according to the invention with coated interconnectors. In particular, the interconnectors can be coated with a material with a lower melting temperature than the adhesive layer, which facilitates soldering to the photovoltaic cell. In this use, it is particularly advantageous for the support film to form the protective layer on the back of the photovoltaic module called the “backsheet” of the photovoltaic module.

### D. Photovoltaic Module

According to yet another aspect, the invention relates to a photovoltaic module comprising at least one multilayer structure as described above. The multilayer structure can be used, notably, as an encapsulant for at least one photovoltaic cell (10). The support film of the multilayer structure can, moreover, according to a preferred embodiment, serve as a protective layer on the back of the module (“back-sheet”) (26).

### E. Process for Manufacturing a Photovoltaic Module

According to yet another aspect, the invention relates to a process for preparing a photovoltaic module, comprising a step of encapsulating at least one photovoltaic cell (10) with a multilayer structure as defined previously.

The multilayer structure, more particularly the adhesive layer thereof, is notably in direct contact with said photovoltaic cell (10), notably with at least one electrical interconnector (18) connecting two photovoltaic cells (12).

According to one embodiment, the step of encapsulating at least one photovoltaic cell (10) comprises the steps of:
(i) placing the adhesive layer (22) of the multilayer structure in contact with at least one electrical interconnector (18) at a temperature below the melting temperature of the adhesive layer (22), notably 5 to 20° C. below the melting temperature of the adhesive layer (22), conventionally at a temperature of between 7° and 80° C., thereby obtaining at least one electrical interconnector (18) attached to the surface of the adhesive layer of the multilayer structure;
(ii) laminating the multilayer structure fixing at least one electrical interconnector obtained in the previous step to the other components of the photovoltaic cell (10), notably at a temperature between the melting temperature of the adhesive layer and the flow temperature of the backsheet, notably between 14° and 160° C.

According to a particular embodiment, the electrical interconnectors (18) can notably be arranged on the surface of the adhesive layer (22) of the multilayer structure in the form of parallel wires or strips. They may be attached to the surface of the adhesive layer (22) by contact with the adhesive layer (22), which may have been heated to a temperature of between 5° and 100° C. so as to render it tacky. The multilayer structure, incorporating the interconnectors (18), obtained in step i) can then be placed on the other components of the photovoltaic module, notably the photovoltaic cells (10).

In order to facilitate assembly of the module, the interconnectors can be coated with a polymer having a lower temperature than that of the adhesive layer.

Preferably, the peel strength of the interface between the adhesive layer (22) and the metal filaments used as electrical interconnectors (18) in the module is at least 0.1 N/cm, preferably at least 0.2 N/cm at an angle of 90°, at room temperature.

### EXAMPLES

### Materials Used

### Polyolefins A

A Affinity PL1880G: Ethylene-octene copolymer, sold by Dow Chemicals
B EVA 1010 VN3: Ethylene vinyl acetate copolymer, sold by Total
C LDPE 1022 FN24: Linear low density polyethylene, sold by Total

### Functionalized Polyolefin

Lotader® 3210: terpolymer of ethylene, butyl acrylate and maleic anhydride, sold by SK Functional Polyolefins

### Additives

Adhesive masterbatch MB4 sold by the company Arkema France: Adhesion promoter on glass containing a silane
Masterbatch UVB: Masterbatch containing a UV stabilizer

Apolhya Solar® LP91H3-UVB containing 80% by weight of backbone-forming polyolefin having maleic anhydride functions bonded to 20% by weight of polyamide 6 grafts. The product has an MFI (Melt Flow Index) of 0.5 g/10 min at 230° C. under 2.16 kg and a melting point of 216° C.

Apolhya Solar® LC3-UV containing 80% by weight of backbone-forming polyolefin having maleic anhydride functions bonded to 20% by weight of copolyamide 6.12 grafts. The product has an MFI (Melt Flow Index) of 10 g/10 min at 230° C. under 2.16 kg and a melting point of 130° C.

TABLE 1

| | | Ex. 1 | Ex. 2 | Ex. 3 |
|---|---|---|---|---|
| Adhesive | Function- | 20% | 20% | 20% |
| layer | alized | | | |
| (40 μm) | polyolefin | | | |
| | Polyolefin | 71% (A) | 71% (B) | 71% (C) |
| | A | | | |
| | Adhesive | 5% | 5% | 5% |
| | master- | | | |
| | batch | | | |
| | MB4 | | | |
| | UVB | 4% | 4% | 4% |
| | master- | | | |
| | batch | | | |

| | | | |
|---|---|---|---|
| Support film (30 μm) | Apolhya | Apolhya | Apolhya |
| | Solar | Solar | Solar |
| | LP91H3-UVB | LP91H3-UVB | LP91H3-UVB |

Constitution of the films according to Examples 1 to 3

### Preparation of the Film

70 μm thick films were made by flat film extrusion (cast) on a Dr COLLIN brand extrusion line. This extrusion line consists of three extruders equipped with a standard polyolefin screw profile, a variable coextrusion block (variable feed block), and a 250 mm coat hanger die. The coextrusion block allows the production of a two-layer film (layer 1/layer 2) with a variable thickness distribution.

### Examples 1 to 3

Adhesive layer formulations were prepared by dry blending a functionalized polyolefin and a polyolefin A as shown in Table 1 above. Films comprising an adhesive layer and a support film were then prepared by coextrusion according to the indications in Table 1 under the following conditions:
Extrusion temperature of the adhesive layer: 150° C.,
Support film extrusion temperature: 240° C.,
Temperature of the coextrusion head and die: 220° C.,
Line speed: 6 m/mn.

### Example 4 (Comparative)

A film was prepared by coextrusion as indicated in the preceding examples, except that the functionalized polyolefin and polyolefin A formulation was replaced with Apolyha Solar LC3-UV.

### Example 5 (Comparative)

A monolayer film of Apolhya Solar LP91H3-UVB was prepared by extrusion under the following conditions:
Extrusion temperature, coextrusion head and die: 240° C.,
Line speed: 6 m/mn.

### Film Evaluation

The films were characterized by measuring the melting temperature of the adhesive layer, by DSC according to the standard ISO11357-1/-3. Moreover, the adhesion between films and metal filaments used as connections of the photovoltaic modules was evaluated according to the following protocol:
10 tin filaments with a diameter of 25 μm are placed side by side parallel to the contact with the adhesive layer of the films;
welding is performed by pressing at 130° C. under 5 bar for 2 s; and
the adhesion force between the filaments and the film is evaluated by means of a free-angle peel test, using a dynamometer in which the filaments are held by one jaw and the film by the other. The equilibrium force during delamination propagation is measured.

The results of these evaluations are given in Table 2 below.

TABLE 2

| | Ex. 1 | Ex. 2 | Ex. 3 | Ex. 4 | Ex. 5 |
|---|---|---|---|---|---|
| Adhesive layer | 99 | 98 | 110 | 130 | 216 |
| melting point (° C.) | | | | | |
| Peel force on | 0.25 | 0.39 | 0.12 | <0.1 | 0 |
| filament (N) | | | | | |

Film evaluation results

These results show that the multilayer structures according to the invention are characterized by a higher peel strength than those obtained with a structure whose adhesive layer does not comprise a combination of functional polyolefin/and polyolefin A as defined in the present invention, but rather a polyolefin grafted with polyamide grafts with a melting point of 130° C. (Example 4) or monolayer structures (Example 5).

Moreover, these results show that adhesive layer matrices with a melting point of between 80° C. and 120° C. can considerably increase the adhesion to the metal filaments.

1. A multilayer structure comprising an adhesive layer and a layer forming a support film in direct contact therewith, wherein
(a) said adhesive layer comprises:
a polyolefin A chosen from a homopolymer of ethylene and a copolymer of ethylene and an α-olefin, a copolymer of ethylene and a vinyl ester of carboxylic acid, notably a vinyl acetate (EVA) or a (co)polymer including methyl, ethyl, propyl, n-butyl, sec-butyl, isobutyl or tert-butyl (meth)acrylate units; and
-a functionalized polyolefin, distinct from polyolefin A, comprising a polyolefin backbone containing a residue of at least one unsaturated monomer (Y), the unsaturated monomer residue (Y) being fixed to the backbone by grafting or copolymerization;
the melting temperature of the adhesive layer being between 80° C. and 120° C.,
(b) said support film comprises a polyamide graft polymer comprising:
a polyolefin backbone, representing from 50% to 95% by mass of the polyamide graft polymer, containing a residue of at least one unsaturated monomer (X) and at least one polyamide graft, representing from 5% to 50% by mass of said polyamide graft polymer, wherein:
the polyamide graft is attached to the polyolefin backbone by the unsaturated monomer residue (X) comprising a function that is capable of reacting by condensation reaction with a polyamide having at least one amine end and/or at least one carboxylic acid end,
the unsaturated monomer residue (X) is fixed to the backbone by grafting or copolymerization,
the polyolefin backbone and the polyamide graft being chosen such that said polyamide graft polymer has a flow temperature greater than 160° C., as measured by DSC according to ISO 11357-1:2016, ISO 11357-2:2020, ISO 11357-3:2018, said flow temperature being defined as the highest temperature among the melting temperatures and the glass transition temperatures of the polyamide graft and of the polyolefin backbone.

2. The multilayer structure as claimed in claim 1, wherein the melting temperature of said adhesive layer is between 90° C. and 110° C.

3. The multilayer structure as claimed in claim 1, wherein said adhesive layer has a Melt Flow Index (MFI), as measured according to the ASTP standard D 1238 at 190° C. under 2.16 kg, of between 0.2 and 10 g/10 min.

4. The multilayer structure as claimed in claim 1, wherein said adhesive layer comprises:
from 65% to 95% by weight of polyolefin A;
from 5% to 35% by weight of functional polyolefin; and
from 0 to 5% by weight of one or more additives.

5. The multilayer structure as claimed in claim 1, wherein the thickness of said adhesive layer is between 20 and 60 μm.

6. The multilayer structure as claimed in claim 1, wherein the thickness of said support film is between 5 and 40 μm.

7. The multilayer structure as claimed in claim 1, wherein the α-olefin comonomer of polyolefin A of the adhesive layer is chosen from ethylene-propylene, ethylene-butene and ethylene-octene.

8. The multilayer structure as claimed in claim 1, wherein the functional polyolefin of said adhesive layer is a polyolefin containing a residue of at least one unsaturated monomer (Y) which is maleic anhydride.

9. The multilayer structure as claimed in claim 1, wherein said support film has a Melt Flow Index (MFI), as measured according to the ASTP standard D 1238 at 230° C. under 2.16 kg, of between 0.2 and 10 g/10 min.

10. The multilayer structure as claimed in claim 1, wherein said support film bears said adhesive layer on one of its faces.

11. The multilayer structure as claimed in claim 1, wherein said support film bears said adhesive layer on both faces.

12. A process for preparing a multilayer structure as claimed in claim 1, wherein said support film is assembled with said adhesive layer by coextrusion.

13. Use of a multilayer structure as claimed in claim 1, for manufacturing photovoltaic modules.

14. A process for preparing a photovoltaic module, wherein a photovoltaic cell is encapsulated with a multilayer structure as claimed in claim 1.

15. The process as claimed in claim 14, wherein the encapsulation comprises the steps of:
(i) attaching an electrically conductive filament to the surface of the adhesive layer of a multilayer structure as claimed in one of claims 1 to 11 at a temperature lower than the melting temperature of the adhesive layer, to form an assembly;
(ii) placing said assembly in contact with a photovoltaic cell at a temperature between the melting temperature of the adhesive layer and the flow temperature of the support film.

16. A photovoltaic module comprising a multilayer structure as claimed in claim 1.
